(19) United States
(12) Patent Application Publication
(10) Pub. No.: US 2019/0165383 A1
(43) Pub. Date: May 30, 2019

(54) LAYERED STRUCTURE, ELECTRONIC DEVICE INCLUDING LAYERED STRUCTURE, SYSTEM INCLUDING ELECTRONIC DEVICE, AND METHOD OF MANUFACTURING LAYERED STRUCTURE

(71) Applicants: FLOSFIA INC., Kyoto (JP); EYETEC CO., LTD., Fukui (JP); KYOTO UNIVERSITY, Kyoto (JP)

(72) Inventors: Shizuo FUJITA, Kyoto (JP); Masafumi ONO, Kyoto (JP); Takayuki UCHIDA, Kyoto (JP); Kentaro KANEKO, Kyoto (JP); Takashi TANAKA, Fukui (JP); Shingo YAGYU, Kyoto (JP); Takashi SHINOHE, Kyoto (JP); Takuto IGAWA, Kyoto (JP)

(21) Appl. No.: 16/197,592

(22) Filed: Nov. 21, 2018

(30) Foreign Application Priority Data
Nov. 29, 2017 (JP) 2017-228487

(51) Int. Cl. H01M 8/0228; H01M 8/026; H01M 8/021; H01M 8/0215; C23C 16/40; C23C 16/448

(52) U.S. Cl. CPC H01M 8/0228; H01M 8/026; C23C 16/4485; H01M 8/0215; C23C 16/407; H01M 8/021

(57) ABSTRACT

In a first aspect of a present inventive subject matter, a layered structure includes a base including a first metal as a major component and a second metal that is different from the first metal, and a thermal oxide film of the base arranged on the base and containing an oxide of the first metal and an oxide of the second metal. The first metal contained in the base is more in atomic composition ratio than the second metal contained in the base. The first metal of the oxide contained in the thermal oxide film is less in atomic composition ratio than the first metal contained in the base. The second metal of the oxide contained in the thermal oxide film is equal to or more in atomic ratio than the first metal of the oxide contained in the thermal oxide film.

### CROSS-REFERENCE TO RELATED APPLICATION

This application is a new U.S. patent application that claims priority benefit of Japanese patent application No. 2017-228487 filed on Nov. 29, 2017, the disclosures of which are incorporated herein by reference in its entirety.

### BACKGROUND OF THE INVENTION

### Field of the Invention

The present disclosure relates to a layered structure, and also relates to an electronic device including a layered structure. The present disclosure relates to a layered structure included in a fuel cell, and also relates to a fuel cell. Also, the present disclosure relates to a system including a layered structure and/or an electronic device. Furthermore, the present disclosure relates to a method of forming a layered structure.

### Description of the Related Art

Layered structures have been suggested as separators of fuel cells in following publications. For example, a polymer electrolyte fuel cell separator has an electrical conductivity to collect power (electricity) which is generated in each single cell by electrically connecting each of the single cells in a fuel cell. The polymer electrolyte fuel cell separator also has a flow path for fluid and gas on its surface, in order to supply fuel gas or oxidizing gas to the cell plane or in order to discharge water, which is generated on the cathode side, with reacted-air. Also, the separator is required to have characteristics such as air tightness for preventing mixing of fuel gas and air, and corrosion resistance for under a power generation environment.

Materials used for the separator include a carbon-based material and a metal material, for example. A separator using the carbon-based material is excellent in corrosion resistance, however, there is a space for improvement in electrical conductivity. Also, in order to obtain sufficient strength and air tightness, the separator using the carbon-based material requires a certain thickness, which results in increase in size and cost of the separator and the fuel cell. On the other hand, a separator using a metal material is easier to be processed and to be reduced in thickness with sufficient robustness and air tightness. However, the separator made of a metal material tends to be corrosive. For a separator required to have a sufficient corrosion resistance, using stainless steel (SUS) has been considered. The separator using stainless steel may be good in corrosion resistance but normally has a passive film on its surface, which causes an increase of contact resistance. Also, even a separator of stainless steel with good corrosion resistance tends to be ionized and eluted when used in a corrosive substance (a strong acid) that is generated in operating environment of a fuel cell. Accordingly, even a separator of stainless steel requires a surface treatment to be resistant to corrosion and to be electrically-conductive as a separator used in such a severe condition.

It is open to the public that a metal separator for a fuel cell including a metal substrate having reactant flow pathways and an electro-conductive anti-corrosion coating layer. The electro-conductive anti-corrosion coating layer covers the surface of the metal substrate on which the reactant flow pathways are formed. The coating layer may include metal carbides, metal oxides, and metal borides. A metal layer for improving adherence is formed between the surface of the metal substrate on which the reactant flow pathways are formed, and the electro-conductive anti-corrosion coating layer (For reference, see Japanese Unexamined Patent Application Publication No. 2006-156386).

Also, it is open to the public that a method of forming a protective film on a surface of a substrate, which consists of an alloy or an oxide containing Cr, and the substrate is used for a fuel cell. When the protective film is formed as a first electrodeposition coating film, a mixture of anionic resin containing more than 30 mass percent of metal oxide fine particles in solid content is used. Also, the method includes a washing process of the first electrodeposition coating film. After the washing process of the first electrodeposition coating film, a second electrodeposition coating film is formed on the first electrodeposition coating film. Then, the first and second electrodeposition coating films are sintered to burn off resin components of the first and second electrodeposition coating films to form a protection film consisting of metal oxide (For reference, see Japanese Unexamined Patent Application Publication No. 2014-067491).

Furthermore, it is open to the public that a method of forming a film containing an electrically-conductive oxide on a substrate by use of a mist chemical vapor deposition (CVD) method, and a separator for a fuel cell including the film with 0.1 μm to 3 μm in thickness formed on a surface of the substrate including an uneven shape on at least a part of the substrate (For reference, see Japanese Unexamined Patent Application Publication No. 2017-199535).

### SUMMARY OF THE INVENTION

In a first aspect of a present inventive subject matter, a layered structure includes a base containing a first metal as a major component and a second metal that is different from the first metal, and a thermal oxide film of the base arranged on the base and containing an oxide of the first metal and an oxide of the second metal. The first metal contained in the base is more in atomic composition ratio than the second metal contained in the base. The first metal of the oxide contained in the thermal oxide film is less in atomic composition ratio than the first metal contained in the base. The second metal of the oxide contained in the thermal oxide film is equal to or more in atomic ratio than the first metal of the oxide contained in the thermal oxide film.

According to an embodiment of a layered structure of a present inventive subject matter, the first metal contains iron (Fe).

Also, according to an embodiment of a layered structure of a present inventive subject matter, the first metal contains aluminum (Al).

It is suggested that the second metal may contain a metal selected from metals of Group 6 in the periodic table.

Also, according to an embodiment of a layered structure of a present inventive subject matter, the base contains stainless steel.

According to an embodiment of a present inventive subject matter, the base may include an uneven shape on at least a part of a surface of the base.

According to an embodiment of a present inventive subject matter, the uneven shape of the base may include grooves. Also, according to an embodiment, the base may be a separator, which may be also called as a bipolar plate. Furthermore, it is suggested that a layered structure may further include a film containing an electrically-conductive oxide and arranged on at least a part of the thermal oxide film.

In a second aspect of a present inventive subject matter, a layered structure includes a base containing a first metal as a major component and a second metal that is different from the first metal; a thermal oxide film of the base arranged on the base and containing an oxide of the first metal and an oxide of the second metal; and a film containing an electrically-conductive oxide and arranged on at least a part of the thermal oxide film. The first metal contained in the base is more in atomic composition ratio than the second metal contained in the base. The first metal of the oxide contained in the thermal oxide film is less in atomic composition ratio than the first metal contained in the base, and the second metal of the oxide contained in the thermal oxide film is equal to or more in atomic ratio than the first metal of the oxide contained in the thermal oxide film.

It is suggested that the electrically-conductive oxide comprised in the film may contain at least one metal selected from among tin (Sn), titanium (Ti), zirconium (Zr), zinc (Zn), indium (In) and gallium (Ga).

Also, it is suggested that the film may further contain at least one chemical element selected from among niobium (Nb), fluorine (F), antimony (Sb), bismuth (Bi), selenium (Se), tellurium (Te), chlorine (Cl), bromine (Br), iodine (I), vanadium (V), phosphorus (P) and tantalum (Ta).

Furthermore, it is suggested that the second metal contains chromium (Cr).

Also, it is suggested that the thermal oxide film of the base may be in a range of 1 nm to 100 nm in thickness.

Furthermore, an electronic device including a layered structure according to an embodiment of a present inventive subject matter is suggested.

According to an embodiment, the electronic device including the layered structure include a fuel cell.

Also, according to an embodiment, a system including an electronic device that includes the layered structure is suggested.

In a third aspect of a present inventive subject matter, a method of manufacturing a layered structure includes heat-treating a base that contains a first metal as a major component and a second metal that is different from the first metal to form a thermal oxide film containing an oxide of the first metal and an oxide of the second metal on the base; and etching the thermal oxide film on the base after the heat-treating the base to decrease the first metal of the oxide contained in the thermal oxide film on the base.

Also, it is suggested that the heat-treating the base is conducted at a temperature that is 400° C. or more.

Furthermore, it is suggested that the heat-treating the base is conducted under an atmosphere containing oxygen.

Also, it is suggested that the method further includes heat-treating the thermal oxide film on the base after the etching the thermal oxide film on the base such that the second metal of the oxide comprised in the thermal oxide film is equal to or more than the first metal of the oxide contained in the thermal oxide film.

Furthermore, it is suggested that the etching the thermal oxide film on the base after the heat-treating may be electrolyte etching.

### BRIEF DESCRIPTION OF THE DRAWING

FIG. 1A shows a schematic perspective view of a layered structure of a first embodiment according to a present inventive subject matter.

FIG. 1B shows an enlarged part of a schematic side view of the layered structure shown in a dotted enclosure IB in FIG. 1A.

FIG. 1C shows an enlarged part of a schematic side view of a layered structure as a second embodiment according to a present inventive subject matter, showing the layered structure including a base, a thermal oxide film formed on the base, and a film containing an electrically-conductive oxide on the thermal oxide film.

FIG. 2A shows a schematic perspective view of a layered structure of a third embodiment according to a present inventive subject matter, showing the layered structure including a base including an uneven shape on at least a part of the base, a thermal oxide film arranged on the base, and a film containing an electrically-conductive oxide arranged on the thermal oxide film.

FIG. 2B shows a schematic cross-sectional view of a part of a layered structure taken along a dash-dotted line IIB-IIB shown in FIG. 2A, showing the layered structure including a base with an uneven shape and a thermal oxide film arranged on the uneven shape of the base.

FIG. 2C shows a schematic cross-sectional view of a part of a layered structure of a fourth embodiment according to a present inventive subject matter, showing a layered structure including a base with an uneven shape, a thermal oxide film arranged on the uneven shape of the base, and a film containing an electrically-conductive oxide and arranged on the thermal oxide film.

FIG. 3A shows a schematic perspective view of a layered structure of a fifth embodiment according to a present inventive subject matter.

FIG. 3B shows a schematic cross-sectional view of a part of a layered structure with a thermal oxide film on a base taken along a dash-dotted line IIIB-IIIB shown in FIG. 3A.

FIG. 3C shows a schematic cross-sectional view of a part of a layered structure with a film containing an electrically-conductive oxide on a thermal oxide film on a base taken along a dash-dotted line IIB-IIB shown in FIG. 3A.

FIG. 4 shows a schematic plan view of an example of a base, which may be used as a separator of a fuel cell.

FIG. 5 shows a schematic perspective view of a fuel cell of a seventh embodiment according to a present inventive subject matter.

FIG. 6 shows a schematic diagram of a fuel cell system of an eighth embodiment according to a present inventive subject matter.

FIG. 7 shows a schematic diagram of a mist chemical vapor deposition (CVD) apparatus that may be used according to an embodiment of method of a present inventive subject matter.

FIG. 8 shows a measurement result of Cr in a thermal oxide film of an embodiment measured by X-ray photoelectron spectroscopy (XPS).

FIG. 9 shows a measurement result of Fe in a thermal oxide film of an embodiment measured by XPS.

FIG. 10 shows a measurement result of a ratio of chemical elements Cr and Fe measured by XPS.

FIG. 11 shows an evaluation result of power generation efficiency of practical examples 1, 2 and comparative example 1.

FIG. 12 shows secondary-ion mass spectrometry (SIMS) analysis result of the practical example 1.

FIG. 13 shows a SIMS analysis result of the comparative example 1.

FIG. 14A shows a photograph of an exterior of the FTO film on the thermal oxide film of the base as a separator for anode (hydrogen fuel electrode), showing the FTO film adhered to the base through the thermal oxide film firmly without a separation of the FTO film.

FIG. 14B shows a photograph of an exterior of the FTO film on the thermal oxide film of the base as a separator for cathode (air electrode), showing the FTO film adhered to the base through the thermal oxide film firmly without a separation.

### DETAILED DESCRIPTION OF EMBODIMENTS

The terminology used herein is for the purpose of describing particular embodiments only and is not intended to be limiting of the subject matter. As used herein, the singular forms “a”, “an” and “the” are intended to include the plural forms as well, unless the context clearly indicates otherwise.

As used herein, the term “and/or” includes any and all combinations of one or more of the associated listed items.

As illustrated in the figures submitted herewith, some sizes of structures or portions may be exaggerated relative to other structures or portions for illustrative purposes. Relative terms such as “below” or “above” or “upper” or “lower” may be used herein to describe a relationship of one element, layer or region to another element, layer or region as illustrated in the figures. It will be understood that these terms are intended to encompass different orientations of a layer, a device, and/or a system in addition to the orientation depicted in the figures.

In a first aspect of a present inventive subject matter, a layered structure includes a base containing a first metal as a major component and a second metal that is different from the first metal, and a thermal oxide film of the base arranged on the base and containing an oxide of the first metal and an oxide of the second metal. The first metal contained in the base is more in atomic composition ratio than the second metal contained in the base. The first metal of the oxide contained in the thermal oxide film is less in atomic composition ratio than the first metal contained in the base. The second metal of the oxide contained in the thermal oxide film is equal to or more in atomic ratio than the first metal of the oxide contained in the thermal oxide film.

Inventors of a present inventive subject matter suggest a layered structure including a base containing a first metal and a second metal, and a thermal oxide film containing an oxide of the first metal and an oxide of the second metal of the base, in that atomic composition ratios of the first metal and the second metal contained in the thermal oxide film are changed to enhance adhesiveness of a film to the base through the thermal oxide film.

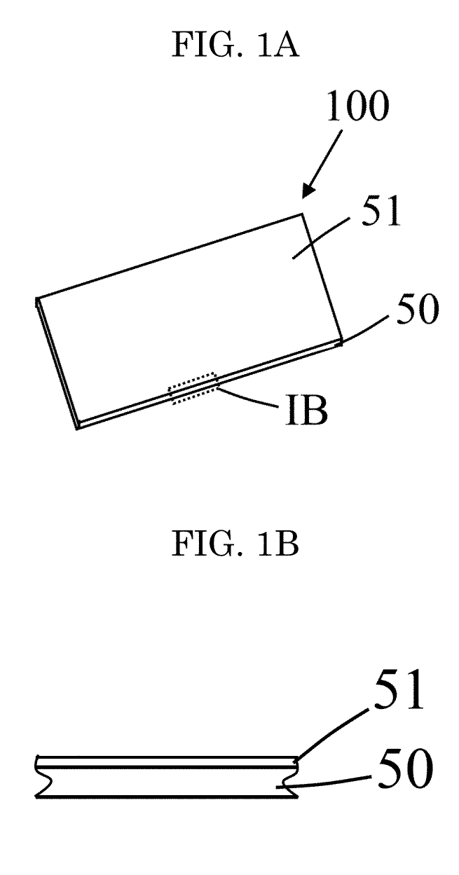

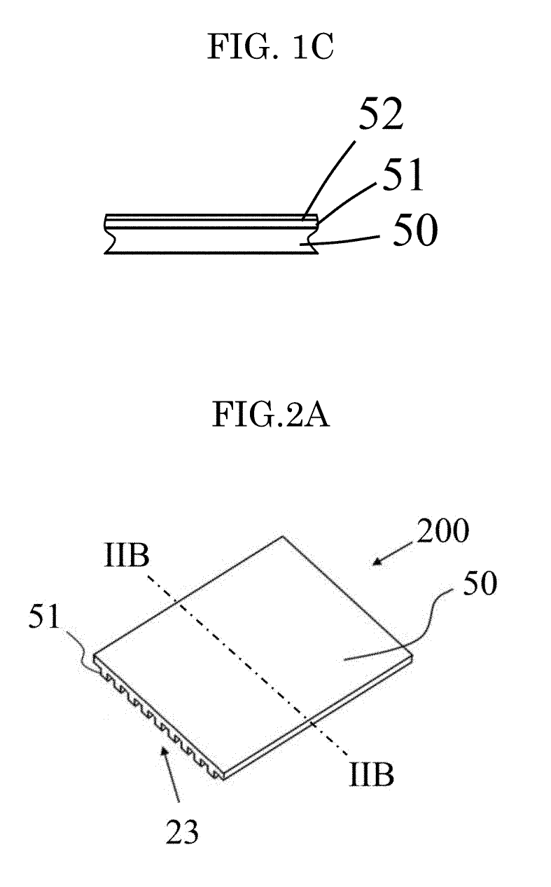

FIG. 1A shows a schematic perspective view of a layered structure of a first embodiment according to a present inventive subject matter. FIG. 1B shows an enlarged part of a schematic side view of the layered structure shown in a dotted enclosure IB in FIG. 1A.

A layered structure 100 includes a base 50 including a first metal as a major component and a second metal that is different from the first metal. The layered structure 100 further includes a thermal oxide film 51 arranged on the base 50. The thermal oxide film 51 contains an oxide of the first metal and an oxide of the second metal.

FIG. 1C shows an enlarged part of a schematic side view of a layered structure as a second embodiment according to a present inventive subject matter, showing the layered structure including a base, a thermal oxide film formed on the base, and a film containing an electrically-conductive oxide on the thermal oxide film.

In this embodiment, the layered structure includes a base 50 including a first metal as a major component and a second metal that is different from the first metal. The layered structure 100 further includes a thermal oxide film 51 arranged on the base 50 and a film 52 containing an electrically-conductive oxide and arranged on at least a part of the thermal oxide film 51. In this embodiment, the base has a flat surface. The thermal oxide film 51 may be entirely arranged on the base.

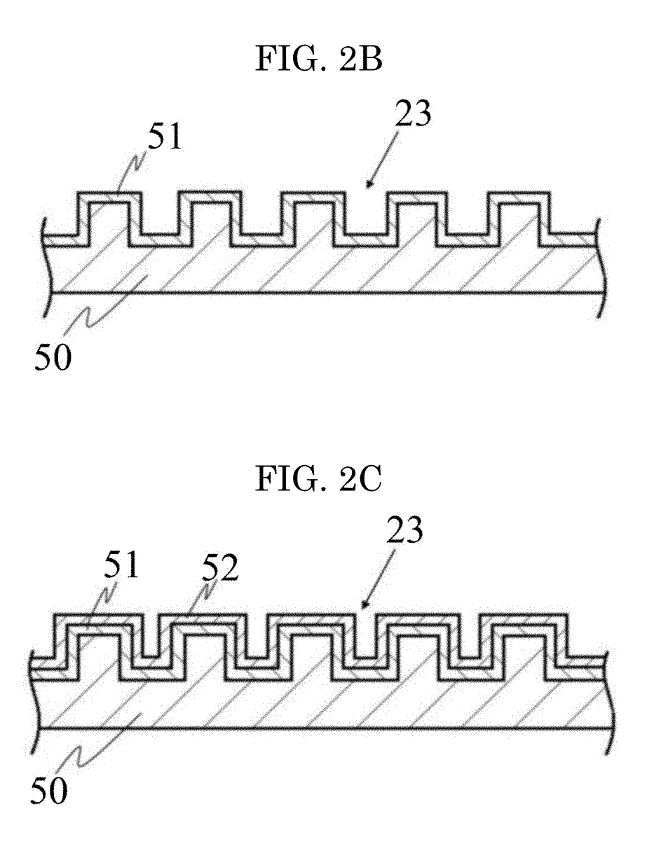

FIG. 2A shows a schematic perspective view of a layered structure of a third embodiment according to a present inventive subject matter. The layered structure 200 includes a base 50 that includes an uneven shape 23 on at least a part of the base 50. FIG. 2B shows a schematic cross-sectional view of a part of a layered structure taken along a dash-dotted line IIB-IIB shown in FIG. 2A. In the layered structure 200, a thermal oxide film 51 is arranged on the uneven shape 23. FIG. 2C shows a schematic cross-sectional view of a part of a layered structure of a fourth embodiment according to a present inventive subject matter, showing a layered structure including a base 50 with an uneven shape 23, a thermal oxide film 51 arranged on the uneven shape 23 of the base 50, and a film 51 containing an electrically-conductive metal oxide and arranged on the thermal oxide film 51.

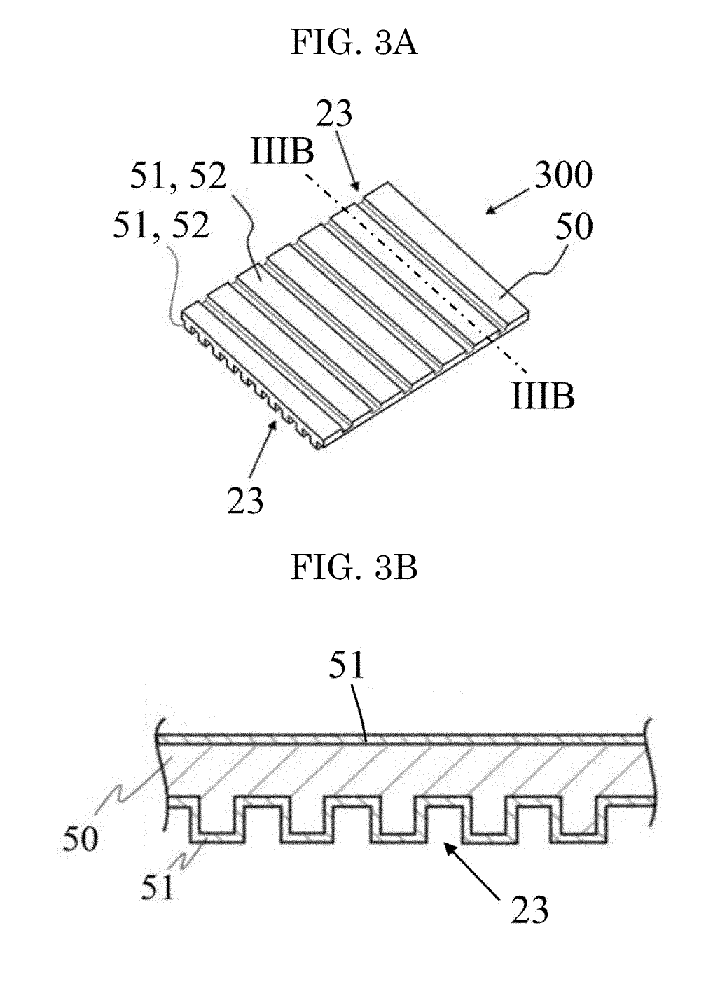

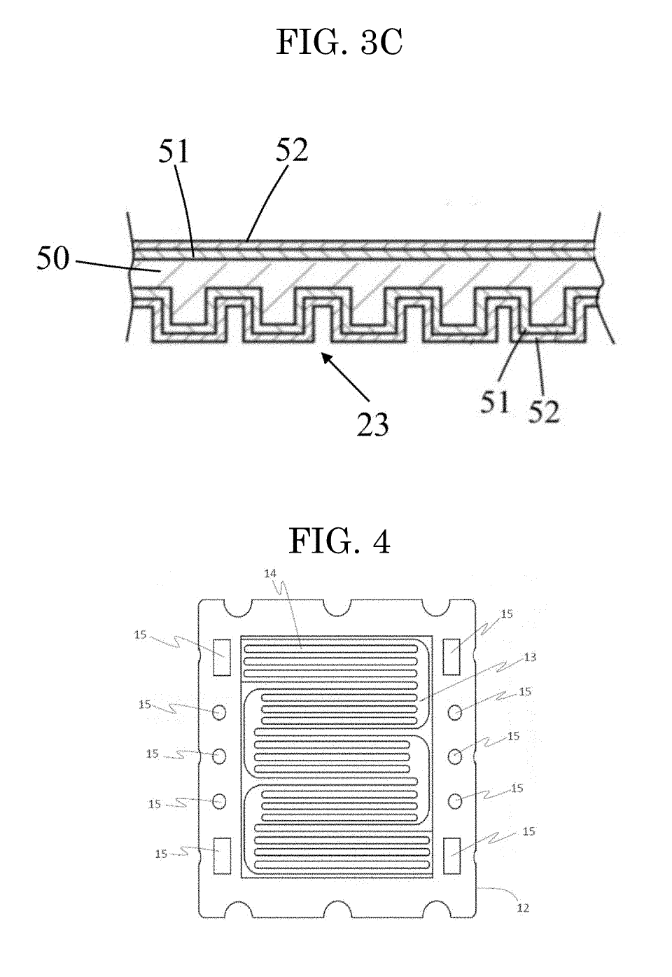

Also, FIG. 3A shows a schematic perspective view of a layered structure of a fifth embodiment according to a present inventive subject matter. The layered structure 300 includes an uneven shape on a first surface and a second surface that is opposite to the first surface. The uneven shape 23 on the first surface of the base 50 are grooves arranged in parallel. Also, the uneven shape 23 on the second surface of the base 50 are grooves arranged in parallel. The grooves on the first surface and grooves on the second surface may be arranged to cross in a plan view, for example. FIG. 3B shows a schematic cross-sectional view of a part of a layered structure with a thermal oxide film 51 on the first surface and the second surface of the base taken along a dash-dotted line IIIB-IIIB shown in FIG. 3A.

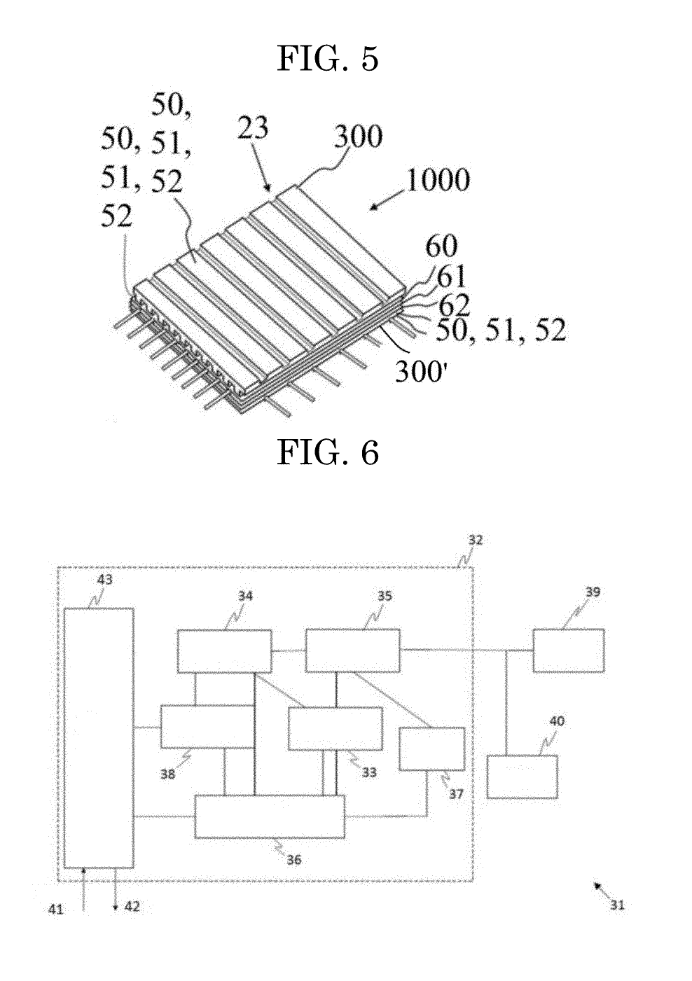

FIG. 3C shows a schematic cross-sectional view of a part of a layered structure with a film 52 containing an electrically-conductive oxide on a thermal oxide film 51 on a base 50 taken along a dash-dotted line IIB-IIB shown in FIG. 3A. The layered structure 300 in this embodiment may be used as separators 300, 300′ in a fuel cell 1000 as shown in FIG. 5.

Furthermore, a layered structure according to an embodiment of a present inventive subject matter including a base, a thermal oxide film of the base, and a film adhered to the base through the thermal oxide film in that atomic composition ratios of the first metal and the second metal are changed to enhance adhesiveness of a film to the base through the thermal oxide film may be used on an exterior part of an electronic device, a lighting system, a building, and a vehicle, for example. Also, the layered structure may be used in an electronic part that requires corrosive resistance.

The first metal may contain one or more metals and not particularly limited as long as an object of a present inventive subject matter is not interfered with. Also, the second metal may contain one or more metals and not particularly limited as long as an object of a present inventive subject matter is not interfered with. Examples of the first metal and the second metal include metals in the d-block of the periodic table.

According to an embodiment of a layered structure, the first metal contained in the base 50 and the thermal oxide film 51 may contain iron (Fe). Also, according to an embodiment of a layered structure of a present inventive subject matter, the first metal contained in the base and in the thermal oxide film 50 may contain aluminum (Al). The second metal contained in the base 50 and the thermal oxide film 51 may contain a metal selected from metals of Group 6 in the periodic table. According to an embodiment of a present inventive subject matter, the metal contained in the thermal oxide film 51 preferably contains chromium (Cr).

The base is not particularly limited as long as the base contains at least a first metal and a second metal that is different from the first metal, the first metal is more in atomic composition ratio than the second metal, and the base contains the first metal as a major component, however, the base preferably contains stainless steel as a constituent material. The base further preferably contains iron (Fe) as a major component. The term “major component” herein means that the major component is contained in the base more than any other components. If the first metal of the base of stainless steel is iron (Fe) as an embodiment of a present inventive subject matter, Fe preferably accounts for 30% or more in atomic ratio in all components contained in the base of stainless steel. Also, Fe as the first metal preferably accounts for 50% or more, and further preferably accounts for 70% or more in atomic ratio in all components contained in the base of stainless steel. This means that the first metal as a major component may account for 50% or less in atomic ratio in all components contained in the base, and also may account for approximately 100% in atomic ratio in the base.

The stainless steel is not particularly limited as long as an object of a present inventive subject matter is not interfered with, and the stainless steel may be a known stainless steel. Examples of the stainless steel may include ferritic stainless steel, martensitic stainless steel, and austenitic stainless steel. Examples of the ferritic stainless steel include SUS430, SUS434, and SUS405. Examples of the martensitic stainless steel include SUS403, SUS410, and SUS431. Examples of the austenitic stainless steel include SUS201, SUS304, SUS304L, SUS304LN, SUS310S, SUS316, SUS316L, SUS317J1, SUS317J2, SUS321, SUS329J1, SUS836, and SUSXM7.

According to an embodiment of a present inventive subject matter, the base of stainless steel is preferably selected from among examples of the austenitic stainless steel.

Also, the base may contain aluminum (Al) as a major component according to an embodiment of a layered structure of a present inventive subject matter. Furthermore, the base may be made of carbon steel or nickel steel. If the base is made of carbon steel, a known carbon steel such as low-carbon steel, medium-carbon steel, and high-carbon steel may be used as long an object of the present inventive subject matter is not interfered with. Examples of low-carbon steel include SS400, SM400, and SM490. Examples of medium-carbon steel include S35C, S45C, and S53C. Examples of high-carbon steel include S55C. Furthermore, if the base is made of nickel steel, a known nickel steel may be used as long an object of the present inventive subject matter is not interfered with. Examples of nickel steel include SL2N255, SL3N255, SL3N275, SL3N440, SL5N590, SL7N590, SL9N520, and SL9N590.

According to embodiments of a present inventive subject matter, the base may include various shapes, on which a thermal oxide film is formed, and a film containing an electrically-conductive oxide is formed through the thermal oxide film. Accordingly, examples of the shape of the base include a plate shape, a flat plate shape and a disk shape, a fibrous shape, a rod shape, a cylindrical shape, a prismatic shape, a tubular shape, a spiral shape, a spherical shape, and a ring shape. According to an embodiment of a present inventive subject matter, the base preferably may have a plate shape. Also, according to an embodiment of the present inventive subject matter, it is preferable that the base has a plate shape, and a thermal oxide film is formed on the base. Furthermore, according to an embodiment of the present inventive subject matter, at least a part of a surface of the base may include an uneven shape.

According to an embodiment of the present inventive subject matter, a film containing an electrically-conductive oxide is uniformly formed with close adhesion even on a base even including an uneven shape through a thermal oxide film of the base. Inventors of a present inventive subject matter suggest a layered structure including a base, a thermal oxide film of the base arranged on the base, and a film containing an electrically-conductive oxide on the thermal oxide film for a separator as an embodiment. The film containing the electrically-conductive oxide was able to be formed with electrical characteristics as a separator by a mist CVD method as explained later. The layered structure is able to be used for various electronic devices and parts including a separator. The base may be made of stainless steel.

FIG. 4 shows a separator, which may be also called as a bipolar plate, as an example. As shown in FIG. 4, the separator 12 includes serpentine flow channels. The base is made of SUS 304 with an uneven shape including a recessed portion 13 and a projected portion 14 formed by press working. The recessed portion may include grooves. Also, the base includes a manifold 15 to supply reaction gas/and or refrigerant to each single cell.

FIG. 5 shows a layered structure used as a separator in a fuel cell, according to an embodiment. The fuel cell 1000 includes an electrolyte 61, a cathode (positive) 60 positioned at a first side of the electrolyte 61, and an anode (negative) 62 positioned at a second side of the electrolyte 61, as shown in FIG. 5, for example. The electrolyte 61 allows positively charged hydrogen ions (protons) to move between the two sides of the fuel cell. The fuel cell 1000 may include a layered structure 300 as a first separator with an uneven shape 23 that faces the cathode 60 and a layered structure 300′ as a second separator with an uneven shape 23 that faces the anode 62. The fuel cell 1000 may be a polymer electrolyte fuel cell. The first separator 300 and the second separator 300′ are electrically conductive to collect electrical power which is generated in a single cell by electrically connecting the cell. The first separator 300 may include a flow path for fluid and/or gas on at least one surface of the first separator 300. The second separator 300′ may include a flow path for fluid and/or gas on at least one surface of the second separator 300′. The first separator 300 and the second separator 300′ each include a base 50, a thermal oxide film 51 of the base 50, and a film 52 containing an electrically-conductive oxide arranged on the thermal oxide film 51 of the base 50. The separators are configured to separate a path for a fuel gas from a path for air (oxygen). Using layered structures 300, 300′ according to an embodiment of a present inventive subject matter as separators with corrosive resistance and electrical stability in a fuel cell, the fuel cell is expected to have long-term stability in electrical properties and corrosive resistance. The film 52 containing an electrically-conductive metal oxide may be a single layer. Also, the film 52 may be a multilayer.

### An Uneven Shape of a Base

The uneven shape may include a recessed portion. Also, the uneven shape may be a projected portion. Also, the uneven shape may include a combination of a recessed portion and a projected portion. The uneven shape may include a concave. The uneven shape may include a groove. The uneven shape may include a convex. The uneven shape may include a ridge. Also, the uneven shape may include recessed portions and/or projected portions that are arranged in a regular pattern and/or arranged with a constant interval. Furthermore, the uneven shape may include recessed portions and/or projected portions that are arranged irregularly. According to an embodiment of a present inventive subject matter, the uneven shape is preferably formed periodically, and further preferably, the uneven shape is formed regularly and periodically.

Moreover, according to an embodiment of the present inventive subject matter, the uneven shape is not particularly limited as long as the uneven shape on which an electrically-conductive metal oxide film is arranged is able to be used as a flow path of gas and/or a fluid of a fuel cell, for example.

Examples of the periodic and regular pattern may include a stripe pattern, a dot pattern, a lattice-like pattern, and a mesh pattern. According to an embodiment of the present inventive subject matter, the periodic and regular pattern preferably is the stripe pattern, the dot pattern, or the lattice-like pattern. The flow path pattern is not particularly limited as long as the flow path pattern work as a flow path for fluid or gas, when the layered structure is applied to as a fuel cell separator. Examples of the flow path pattern may include serpentine type flow path pattern, which contains at least one flow path in a serpentine manner, parallel type pattern, which contains multi straight flow paths in a parallel manner, or a combination of the serpentine type flow path pattern and the parallel type flow path pattern. According to an embodiment of the present inventive subject matter, the flow path pattern is preferably the parallel type flow path pattern. A cross-sectional shape of the recessed portion and a cross-sectional shape of the projected portion are not particularly limited. Examples of a cross-sectional shape of the recessed portion and the projected portion may include a channel shape, a U-shape, a converted U-shape, corrugated shape, polygons including a triangle, a quadrangle (for example, a square, a rectangle or a trapezoid), and/or a polygon including a pentagon and a hexagon. Examples of a planar shape of the recessed portion and/or the projected portion may include a circle, an ellipse, a triangle, a quadrangle (for example, a square, a rectangle, or a trapezoid), and/or a polygon including a pentagon or a hexagon. According to a layered structure used for a separator of a fuel cell as an embodiment of the present inventive subject matter, the planar shape of the recessed portion preferably has a rectangular shape to be a flow path.

A material component of the projected portion is not particularly limited and may be a known material. The projected portion is made of the same material as the material of the base. The projected portion may be a part of the base. The material component of the projected portion may be an electrically-conductive material, or a semiconductor material. Furthermore, the base may include an insulating material. Also, the material component of the projected portion may contain a material component contained in a base. The material component of the projected portion may be amorphous, single crystal, or polycrystalline. Examples of the material component of the projected portion include carbon, diamond, a metal, an oxide, a nitride, and/or a carbide of at least one selected from among silicon (Si), germanium (Ge), titanium (Ti), zirconium (Zr), hafnium (Hf), tantalum (Ta), and tin (Sn), and/or a mixture of at least two of the mentioned examples.

A method of forming the projected portion may be a known method. Examples of the method of forming the projected potion include a photolithography, electron beam lithography, laser patterning, screen printing, etching (for example, dry etching or wet etching), and other known patterning methods. According to an embodiment of a present inventive subject matter, the projected portion preferably has a stripe pattern, a mesh pattern or a lattice-like pattern, and further preferably a lattice-like pattern. The projected portion is also preferable to be a projected portion that is provided by processing the base. A method of processing the base is not particularly limited and a known processing method may be used. Examples of the method of processing the base include etching (for example, dry etching or wet etching), cutting, molding and press working.

The recessed portion is not particularly limited. The component material at the recessed portion may be the same component as the component material of the projected portion. The recessed portion may be formed into the base. According to an embodiment of a present inventive subject matter, the recessed portion preferably has a stripe pattern, a mesh pattern or a lattice-like pattern. A method of forming the recessed portion may be the same method as the method of forming the projected portion. The recessed portion may be a recessed portion that is provided by a mask material. It is also preferable that the recessed portion is a recessed portion that is provided by processing the base. A method of processing the base is not particularly limited and a known groove method may be used. A width, depth and a terrace width of the recessed portion are not particularly limited and may be set appropriately.

According to embodiments of a present inventive subject matter, a layered structure includes a base including a first metal as a major component and a second metal that is different from the first metal, and a thermal oxide film of the base arranged on the base and containing an oxide of the first metal and an oxide of the second metal. The first metal contained in the base is more in atomic composition ratio than the second metal contained in the base. The first metal of the oxide contained in the thermal oxide film is less in atomic composition ratio than the first metal contained in the base. The second metal of the oxide contained in the thermal oxide film is equal to or more in atomic ratio than the first metal of the oxide contained in the thermal oxide film.

Also, according to an embodiment of a present inventive subject matter, a method of manufacturing a layered structure includes heat-treating a base that contains a first metal as a major component and a second metal that is different from the first metal to form a thermal oxide film comprising an oxide of the first metal and an oxide of the second metal on the base; and etching the thermal oxide film on the base after the heat-treating the base to decrease the first metal of the oxide comprised in the thermal oxide film on the base.

Forming the thermal oxide film containing the oxide of the first metal and the oxide of the second metal is not particularly limited as long as an object of a present inventive subject matter is not interfered with, however, according to embodiments of the method of a present inventive subject matter, forming the thermal oxide film containing the oxide of the first metal and the oxide of the second metal is preferably conducted by heat-treating a surface of the base under an atmosphere containing oxygen, etching the thermal oxide film on the base, and heat-treating the thermal oxide film on the base, again. Also, forming the thermal oxide film may be conducted by flash annealing and/or flash etching. The heat-treating the thermal oxide film is preferably conducted in a short time to enhance adhesiveness of the thermal oxide film to the base without two or more layers being formed in the thermal oxide film. Also, the etching the thermal oxide film on the base is to decrease the first metal in the thermal oxide film, however, preferably conducted in a short time to avoid removing the thermal oxide film entirely from the base. The thermal oxide film after the etching is preferably in a range of 1 nm to 100 nm in thickness.

According to an embodiment of a present inventive subject matter, a base made of stainless steel may be used. In this embodiment, a thermal oxide film containing an oxide of iron is formed on at least a part of a surface of the base of stainless steel by heat-treating the base under an atmosphere containing oxygen (for forming a thermal oxide film). The amount of the oxide of iron contained in the thermal oxide film tends to be decreased by etching the thermal oxide film (for decreasing the oxide of iron). After the etching the thermal oxide film, the thermal oxide film is heat-treated again (for adjusting the thermal oxide film).

For forming a thermal oxide film, the thermal oxide film is formed on at least a part of a surface of the base of stainless steel by heat-treating the base under an atmosphere containing oxygen. Also, it is possible to form the thermal oxide film on an entire surface of the base. The heat-treating is not particularly limited, and a known heat-treating using a heater may be used. Heat-treating temperatures are not particularly limited as long as a thermal oxide film that contains an oxide of iron is able to be formed on at least a part of a surface of the base, however, the heat-treating temperatures are preferably 300° C. or more, and further preferably 400° C. or more. Also, an example of an upper limit of the heating temperatures is 1500° C., and the heat-treating temperatures are preferably 1000° C. or less, and further preferably 800° C. or less. Also, the heat-treating may be conducted in any atmosphere of a vacuum, a reducing-gas atmosphere, and an oxidizing-gas atmosphere, however, heat-treating according to embodiments of a method of a present inventive subject matter is preferably conducted under non-vacuum condition, and further preferably conducted under an atmosphere containing oxygen. Also, the heat-treating may be conducted in any condition of under an atmospheric pressure, under an increased pressure, and under a reduced pressure. According to embodiments of a present inventive subject matter, the thermal reaction is preferably conducted under an atmospheric pressure, and further preferably in the air.

For decreasing the oxide of iron, the oxide of iron contained in the thermal oxide film is removed by etching the thermal oxide film. Etching is not particularly limited as long as the amount of the oxide of iron is able to be reduced and/or removed, however, etching the thermal oxide film using acid is preferable. Preferable examples of acid include hydrochloric acid, sulfuric acid, nitric acid, phosphoric acid, fluoroboric acid, hydrofluoric acid, inorganic acid including perchloric acid. A known etching method may be used, and dipping, applying, spraying, and electrolyte etching may be used. For embodiments of a method of a present inventive subject matter, electrolytic etching is preferable for etching a thermal oxide film on a base. Also, the etching the thermal oxide film on the base is preferably conducted within 60 seconds, and further preferably within 30 seconds. Also, heat-treating the base to form a thermal oxide film on a base and etching the thermal oxide film may be repeatedly conducted according to an embodiment of a method of a present inventive subject matter.

The thermal oxide film, from which the oxide of iron is removed by etching the thermal oxide film, is heat-treated again to adjust the atomic composition ratio of the oxide of iron to be less than the atomic composition ratio of the oxide of iron in the thermal oxide film before being etched. Heat-treating conditions and methods to form a thermal oxide film may be also used for heat treating the thermal oxide film after being etched, however, heat-treating is preferably done in a short time to prevent oxides of iron from being dispersed into the thermal oxide film. The heat-treating time is preferably within 10 minutes, and further preferably within five minutes. The reduction rate of the oxide of iron should be 10% or more in element ratio, and preferably 20% or more. Further preferably, the reduction rate of the oxide is 30% or more in element ratio.

A layered structure of a present inventive subject matter is obtainable according to the mentioned above, and according to embodiments of a present inventive subject matter, it is preferable to form a film containing an electrically-conductive oxide on at least a part of a surface of the thermal oxide film of the base.

The electrically-conductive oxide is not particularly limited, as long as the electrically-conductive oxide is an oxide with electrical conductivity, and a known metal oxide may be used. According to embodiments of a present inventive subject matter, the film is preferably an electrically-conductive metal oxide film containing a metal oxide as a major component to enhance corrosive resistance. Metal(s) contained in the metal oxide is not particularly limited, however, according to embodiments of a present inventive subject matter, the film containing an electrically-conductive oxide preferably contains a tetravalent metal. Examples of the tetravalent metal include titanium (Ti), zirconium (Zr), hafnium (Hf), silicon (Si), germanium (Ge), and tin (Sn). In an embodiment of a present inventive subject matter, a layered structure includes a base, a thermal oxide film of the base, and a film preferably containing an oxide of tin arranged on the thermal oxide film arranged on the base.

The film preferably contains the metal oxide as a major component. The term “major component” herein means that the metal oxide is 50% or more in atomic composition ratio in the film. Furthermore, the metal oxide is preferably 70% or more, further preferably 90% or more in atomic composition ratio in the film. Also, the metal oxide may be 100% in atomic composition ratio in the film.

Also, the film may contain a dopant, according to an embodiment of a present inventive subject matter as long as an object of the present inventive subject matter is not interfered with. Examples of the dopant include tin (Sn), germanium (Ge), silicon (Si), titanium (Ti), zirconium (Zr), vanadium (V), niobium (Nb), antimony (Sb), tantalum (Ta), fluorine (F), chlorine (Cl), and cerium (Ce). In embodiments of a present inventive subject matter, the dopant is preferably antimony (Sb) or fluorine (F). The contained amount of dopant in the film is not particularly limited, however, the contained amount of dopant in the film is preferably 0.00001 atomic percent (at. %) or more in composition of the film. Also, the contained amount of dopant in the film is further preferably in a range of 0.00001 at. % to 50 at. %. The contained amount of dopant in the film is most preferably in a rage of 0.00001 at. % to 20 at. %.

Forming the film on a thermal oxide film of the base is explained as follows. The film is arranged on at least a part of the base through the thermal oxide film. Also, it is possible to form the film on an entire surface of the base through the thermal oxide film. The film may be formed on the base by a method, which is not particularly limited and may be a known method, however, according to an embodiment of a method of a present inventive subject matter, the method is preferably a mist CVD method. Specifically, the film is preferably formed on the thermal oxide film of the base by turning a raw material solution containing at least a metal into atomized droplets, carrying the atomized droplets by carrier gas onto the base on which the thermal oxide film is formed, and causing a thermal reaction of the atomized droplets adjacent to the base. Inventors of a present inventive subject matter found that a film containing an electrically-conductive metal oxide is able to be formed by the mist CVD method on a thermal oxide film of the base with atomic composition ratios of metal components in the thermal oxide film changed, and the layered structure that was obtained has enhanced adhesiveness of the film to the base through the thermal oxide film.

### Raw-Material Solution

The raw-material solution is not particularly limited as long as the raw-material solution contains at least one metal, and atomized droplets are able to be formed from the raw-material solution. The raw-material solution may contain an organic material and/or an inorganic material. The at least one metal contained in the raw-material solution is not particularly limited as long as an object of a present inventive subject matter is not interfered with, and may be a metal simple substance and/or a metal compound.

According to embodiments of a present inventive subject matter, the at least one metal preferably contains a tetravalent metal. Examples of the tetravalent metal include titanium (Ti), zirconium (Zr), hafnium (Hf), silicon (Si), germanium (Ge), and tin (Sn). In an embodiment of a present inventive subject matter, the at least one metal preferably contains tin (Sn). The contained amount of the at least one metal in the raw-material solution is not particularly limited, however, preferably in a range of 0.001 weight percent (wt. %) to 80 wt. %, and further preferably in a range of 0.01 wt. % to 80 wt. %.

According to embodiments of a present inventive subject matter, a raw-material solution containing the at least one metal in the form of a complex or salt dissolved or dispersed in an organic solvent or water is preferably used. Examples of the form of the complex include an acetylacetonate complex, a carbonyl complex, an ammine complex, and a hydride complex. Also, examples of the form of the salt include organic metal salts (for example, metal acetate, metal oxalate, metal citrate, etc.), metal sulfide salts, metal nitrate salts, phosphorylated metal salts, metal halide salts (for example, metal chloride salts, metal bromide salts, metal iodide salts, etc.).

A solvent of the raw-material solution is not particularly limited and may be an inorganic solvent including water. Also, a solvent of the raw material solution may be an organic solvent including alcohol. Furthermore, a mixed solvent of water and alcohol may be used. According to embodiments of a present inventive subject matter, a solvent of the raw material solution preferably contains water, and a mixed solvent of water and alcohol is further preferably used, and most preferably, a solvent of the raw material solution is water. Examples of water include pure water, ultrapure water, tap water, well water, mineral water, hot spring water, spring water, fresh water and ocean water. According to embodiments of a present inventive subject matter, ultrapure water is preferable as a solvent of a raw material solution.

Also, an additive that may be a hydrohalic acid and/or an oxidant, for example, may be added into the raw-material solution. Examples of the hydrohalic acid include a hydrobromic acid, a hydrochloric acid, and a hydriodic acid, and among the examples, a hydrobromic acid or a hydriodic acid is preferable. Examples of the oxidant include peroxides such as hydrogen peroxide (H₂O₂), sodium peroxide (Na₂O₂), barium peroxide (BaO₂), benzoyl peroxide (C₆H₅CO)₂O₂, and organic peroxides such as hypochlorous acid (HCIO), perchloric acid, nitric acid, ozone water, peracetic acid, and nitrobenzene.

According to an embodiment of a present inventive subject matter, the raw-material solution preferably contains a dopant, which is used to control electrical conductivity of a film to be obtained. It is possible to obtain an electrically-conductive metal oxide film and also to give electrical conductivity to the base even without using ion plantation. The dopant is not particularly limited as long as an object of a present inventive subject matter is not interfered with. Examples of the dopant may include tin, germanium, silicon, titanium, zirconium, vanadium, niobium, antimony, tantalum, fluorine, chlorine, and cerium. According to embodiments of a present inventive subject matter, the dopant is preferably antimony or fluorine. The dopant concentration in general may be in a range of 1×10¹⁶/cm³ to 1×10²³/cm³. The dopant concentration may be at a lower concentration of, for example, approximately 1×10¹⁸/cm³ or less. According to an embodiment of the present inventive subject matter, the dopant may be contained at a high concentration of, for example, 1×10¹⁹/cm³ or more, and preferably 1×10²⁰/cm³ or more.

### Forming Atomized Droplets from a Raw Material Solution

A raw material solution is turned into atomized droplets floating in a space of a container of a mist generator. The raw material solution may be turned into atomized droplets by a known method, however, according to an embodiment of a present inventive subject matter, the raw material solution is preferably turned into atomized droplets by ultrasonic vibration. Atomized droplets including mist particles, obtained by using ultrasonic vibration and floating in the space have the initial velocity that is zero. Since atomized droplets floating in the space is carriable as gas, the atomized droplets floating in the space are preferable to avoid damage caused by the collision energy without being blown like a spray. The size of droplets is not limited to a particular size, and may be a few mm, however, the size of atomized droplets is preferably 50 μm or less. The size of droplets is further preferably in a range of 1 to 10 μm.

### Carrying Atomized Droplets into a Layer (Film)-Formation Chamber

Atomized droplets floating in the space of a container for forming atomized droplets are carried into a layer (film)-formation chamber by carrier gas. The carrier gas is not particularly limited as long as an object of the present inventive subject matter is not interfered with, and thus, examples of the carrier gas may be an inert gas such as nitrogen and argon, may be an oxidizing gas such as oxygen and ozone, and may be a reducing gas such as a hydrogen gas and a forming gas. The type of carrier gas may be one or more, and a dilution gas at a reduced flow rate (e.g., 10-fold dilution gas) and the like may be used further as a second carrier gas. The carrier gas may be supplied from one or more locations. While the flow rate of the carrier gas is not particularly limited, the flow rate of the carrier gas may be in a range of 0.01 to 20 L/min. According to an embodiment of a present inventive subject matter, the flow rate of the carrier gas may be preferably in a range of 1 to 10 L/min. When a dilution gas is used, the flow rate of the dilution gas is preferably in a range of 0.001 to 10 L/min. According to an embodiment of a present inventive subject matter, when a dilution is used, the flow rate of the dilution gas is further preferably in a range of 0.1 to 5L/min.

### Forming a Film

For forming a film containing an electrically-conductive oxide, the atomized droplets carried into the film (layer)-formation chamber by carrier gas are thermally reacted (through “thermal reaction”) to form a film on a thermal oxide film arranged on a base, which is placed in the film (layer)-formation chamber. Herein, “thermal reaction” works as long as the atomized droplets react by heat, and conditions of reaction are not particularly limited as long as an object of a present inventive subject matter is not interfered with. According to embodiments of a present inventive subject matter, the thermal reaction is conducted at an evaporation temperature or higher temperatures of the evaporation temperature of the solvent in the raw material solution, however, a range of temperature for the “thermal reaction” are not too high and may be below 800° C., for example. The thermal reaction is preferably conducted at a temperature of 600° C. or less, and most preferably at a temperature of 500° C. or less. Also, the thermal reaction may be conducted in any atmosphere of a vacuum, a reducing-gas atmosphere, and an oxidizing-gas atmosphere. Also, the thermal reaction may be conducted in any condition of under an atmospheric pressure, under an increased pressure, and under a reduced pressure. However, according to embodiments of a present inventive subject matter, the thermal reaction is preferably conducted under a non-vacuum, and further preferably under an atmosphere of oxygen. The thermal reaction is preferably conducted under an atmospheric pressure.

By forming the film containing the electrically-conductive oxide as mentioned above, the film is able to be formed on the thermal oxide film of the base even with an uneven shape. The film thickness of a film containing the electrically-conductive oxide to be obtained is easily adjusted by changing a film-formation time.

According to an embodiment of a present inventive subject matter, if the base is made of stainless steel, a layered structure including the base of stainless steel, a thermal oxide film on the base, and a film containing an electrically-conductive oxide is able to be obtained by the method mentioned above with enhanced adhesiveness of the film to the base through the thermal oxide film. Accordingly, a layered structure with long-term stability of an electrical characteristic and corrosion resistance is obtainable.

A layered structure according to an embodiment of a present inventive subject matter, is able to be used for various electronic parts. Examples of various electronic parts include an electric current collector, an electromagnetic wave shield, an electronic part including an electrode, a heat-radiating member, a semiconductor part, a separator of a fuel cell, and a part for a solar cell. Furthermore, the base may be a member required to have corrosion resistance. Accordingly, a layered structure including a base, a thermal oxide film on the base and a film containing an electrically-conductive oxide according to an inventive subject matter may be used at exterior of electronic devices, lighting systems, buildings and vehicles, for example. For more details, examples of electronic devices include a digital camera, a printer, a projector, a device with a CPU such as a personal computer and a smartphone, a device with a power source such as a vacuum cleaner and an electric iron, and a power generator such as a fuel cell power generator. As embodiments of a present inventive subject matter, a layered structure may be used in an electronic device and/or machine with a drive unit. Examples of the electronic device and/or machine with the drive unit include a motor, a drive system, an electric car, an electric cart, an electric wheelchair, an electric toy, an electric airplane, an electric equipment, and a micro electro mechanical system (MEMS).

Also, according to an embodiment of a present inventive subject matter, a system includes at least one electronic device and/or machine including a layered structure and a CPU. FIG. 6 shows a schematic diagram of a power generator of an eighth embodiment according to a present inventive subject matter. The power generator system 31 includes a fuel cell system 32, for example. The fuel cell system 32 includes a CPU 36, a fan blower 37, a fuel cell processor 33 that is configured to generate fuel gas containing hydrogen as a major component from an original gas that may be a utility gas through steam-reforming, water-gas shift reaction, and selective oxidation reaction, and a fuel cell stack 34 that is configured to generate electricity by chemical reaction of the fuel gas and an oxidizing gas. The fuel cell system 32 further includes a heat exchanger 38 to collect heat generated from the fuel cell stack during electric power generation and store as hot water 42, which is originally supplied as tap water 41, in a water storage tank 43. As shown in FIG. 6, the fuel cell system 32 is connected to a commercial alternating current through a distribution switch board 39. Also, home appliances and industrial products are connected as loads 40 between the fuel cell system 32 and the distribution switch board 39. The fuel cell stack 34 starts to generate electricity, which is supplied through an inverter 35 to the loads 40 to be activated, and the heat generated from the fuel cell stack 34 is configured to be efficiently stored in the water storage tank 43. The home appliances and industrial products may be various electronic devices, which are not particularly limited and could be white goods including an air conditioner, a refrigerator, and a washing machine, other audio and/or visual equipment, beauty and/or barber equipment, a personal computer, a video game console, a portable device, machines and/or appliances for business use, and a device with a CPU, for example.

Accordingly, a layered structure of an embodiment of a present inventive subject matter is able to be useful for any system requiring a fuel cell.

Some embodiments are explained as follows, however, set forth only for the purposes of example.

### Practical Example 1

1-1. Forming a Thermal Oxide Film

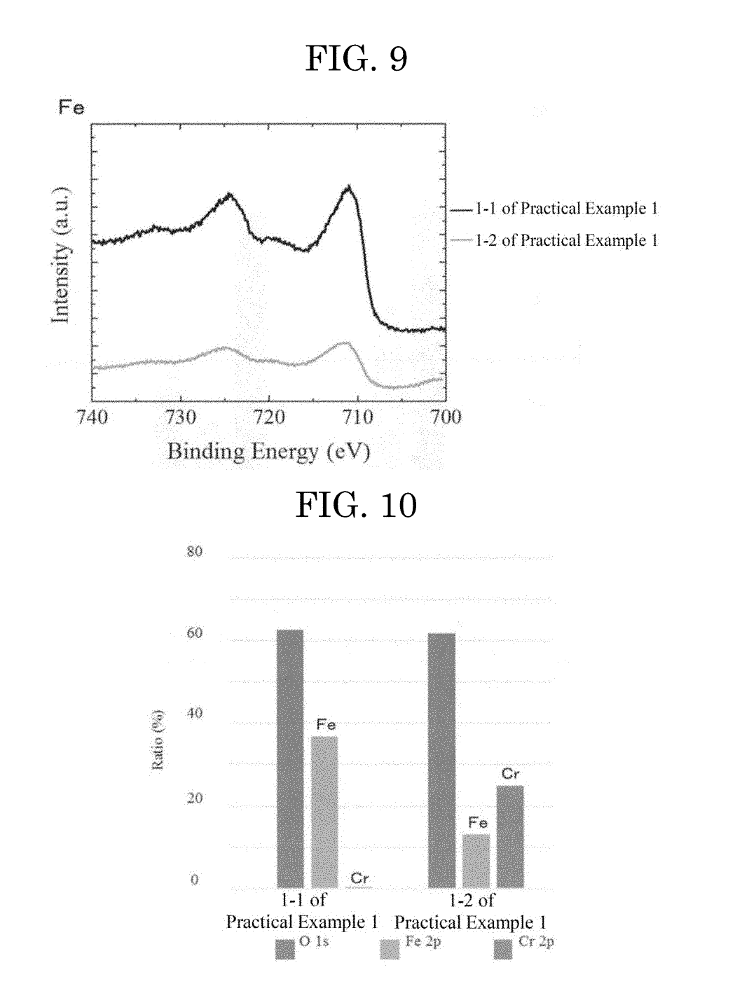

A base made of stainless steel (SUS 304) was arranged on a hot plate. The base in this embodiment has a plate shape to be used as a separator. The base was heat-treated (annealed) at a temperature of 420° C. under an atmosphere of air to form a thermal oxide film on the base. An XPS measurement was done on the thermal oxide film to find if the thermal oxide film contains an oxide of iron (Fe) and an oxide of chromium (Cr), and the XPS measurement results of the thermal oxide film are shown in FIG. 8 to FIG. 10. As clearly shown at 1-1 of Practical Example 1 in FIG. 8, Cr was hardly contained in the thermal oxide film. Also, as clearly shown at 1-1 of Practical Example 1 in FIG. 9, Fe was mainly contained in the thermal oxide film. FIG. 10 shows that the thermal oxide film contains Fe as a major component at 1-1 of Practical Example 1.

1-2. Removing a Portion in which the Oxide of Iron Densely Contained in the Thermal Oxide Film

The thermal oxide film obtained at 1-1 above was soaked in an aqueous solution with 3.7% hydrochloric acid (using a first-class product of Kanto Chemical Co., Inc.) for 10 seconds. The thermal oxide film was soaked in the aqueous solution with 3.7% hydrochloric acid twice both for 10 seconds as etching the thermal oxide film. Then, heat-treating the thermal oxide film at a temperature of 400° C. for two minutes. An XPS measurement was done on the thermal oxide film after the etching, and the surface of the thermal oxide film was observed. The XPS measurement results of the thermal oxide film are shown in FIG. 8 to FIG. 10. As clearly shown at 1-2 of Practical Example 1 in FIG. 8, the thermal oxide film after being etched contained Cr. Also, as clearly shown at 1-2 of Practical Example 1 in FIG. 9, Fe was contained in the thermal oxide film after being etched, however, intensity of Fe peak of the thermal oxide film was significantly weakened. FIG. 10 shows that the thermal oxide film after being etched contains more oxides of Cr than oxides of Fe at 1-2 of Practical Example 1.

1-3. Forming a Fluorine-Doped Tin Oxide (FTO) Film

An FTO film was formed on the thermal oxide film obtained at 1-2 above by use of a mist CVD apparatus, and explained as follows.

1. Film (Layer)-Formation Apparatus

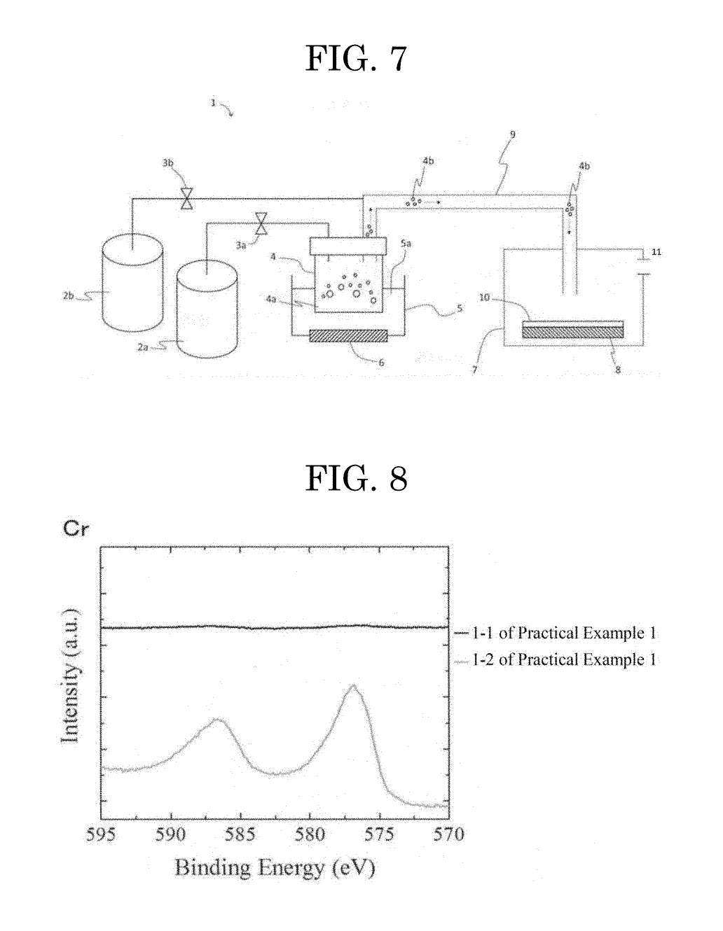

FIG. 7 shows a mist chemical vapor deposition (CVD) apparatus 1 used in this example to form a film containing an electrically-conductive oxide on the thermal oxide film obtained at 1-2 above. The mist CVD apparatus 1 includes a carrier gas supply device 2a, a first flow-control valve 3a to control a flow of a carrier gas that is configured to be sent from the carrier gas supply device 2a, a diluted carrier gas supply device 2b, a second flow-control valve 3b to control a flow of a carrier gas that is configured to be sent from the diluted carrier gas supply device 2b, a mist generator 4 in that a raw material solution 4a is contained, a vessel 5 in that water 5a is contained, and an ultrasonic transducer 6 that may be attached to a bottom surface of the vessel 5. The mist CVD apparatus 1 further includes a film (layer)-formation chamber 7, a supply tube 9 connecting the mist generator 4 to the film (layer)-formation chamber 7, a hot plate 28, and an exhaust port 11 to release atomized droplets and gas after the layer (film) is formed. The hot plate 8 is arranged in the film (layer)-formation chamber 7. A film (layer) is grown on the metal oxide film on the base 10, which is placed on the hot plate 8.

2. Preparation of Raw-Material Solution

A raw-material solution was prepared by tin and fluorine to be 10:1 (tin:fluorine=10:1) in molar ratio in an aqueous solution.

3. Film (Layer) Formation Preparation

The raw-material solution 4a obtained at 2. the Preparation of the Raw-Material Solution above was set in the container of the mist generator 4. Also, a base 10 of stainless steel on that a thermal oxide film is formed was placed on the hot plate 8 as a heater in a film (layer)-formation chamber 7. The hot plate 8 was activated to raise the temperature of the base up to 400° C. The first flow-control valve 3a and the second flow-control valve 3b were opened to supply a carrier gas from the carrier gas device 2a and the diluted carrier gas device 2b, which are the source of carrier gas, into the film (layer)-formation chamber 7 to replace the atmosphere in the film (layer)-formation chamber 7 with the carrier gas sufficiently. After the atmosphere in the film (layer)-formation chamber 7 was sufficiently replaced with the carrier gas, the flow rate of the carrier gas from the carrier gas source 2a was regulated at 2.5 L/min. and the diluted carrier gas from the diluted carrier gas source 2b was regulated at 4.5 L/min. In this example, mixed gas (N₂:O₂=8:2) of nitrogen (N₂) and oxygen (O₂) was used as the carrier gas.

4. Formation of the Film

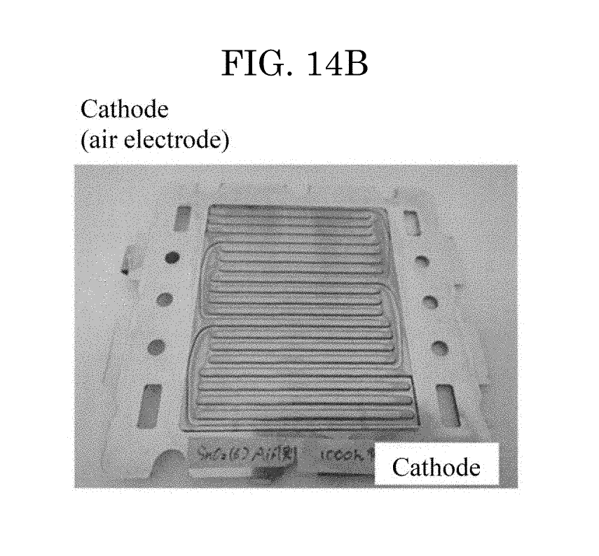

The ultrasonic transducer 6 was then activated to vibrate at 2.4 MHz, and vibrations were propagated through the water 5a in the vessel 5 to the raw material solution 4a to turn the raw material solution 4a into atomized droplets. The atomized droplets 4b were introduced in the film (layer)-formation chamber 7 with the carrier gas, and the atomized droplets heated and thermally reacted adjacent to the base 10 at 400° C. in the film (layer)-formation chamber 7 to be a film on the base 10 was made of SUS 404 in this example. The film obtained on the base 10 was an FTO film. FIG. 14A shows a photograph of an exterior of the FTO film on the thermal oxide film of the base as a separator for anode (hydrogen fuel electrode), showing the FTO film adhered to the base through the thermal oxide film firmly without a separation of the FTO film. Also, FIG. 14B shows a photograph of an exterior of the FTO film on the thermal oxide film of the base as a separator for cathode (air electrode), showing the FTO film adhered to the base through the thermal oxide film firmly without a separation. The FTO films as an electrically-conductive oxide film formed on the thermal oxide film of the bases that are separator plates were in good quality.

### Practical Example 2

As Practical Example 2, a layered structure including an FTO film was obtained as Practical Example 2 under the same conditions as the conditions in the Practical Example 1 except one condition at etching a thermal oxide film, which was obtained according to conditions at 1-1.

For more details, electrolyte etching was conducted on the thermal oxide film in Practical Example 2, while etching by acid-dipping was conducted on the thermal oxide film in Practical Example 1. In the electrolyte etching, the thermal oxide film obtained according to conditions at 1-1 was set to be an anode, to which direct current of 5 A/dm² was applied in an aqueous solution of 3% sulfuric acid aqueous solution (using a first-class product of Kanto Chemical Co., Inc.) for 30 seconds.

### Comparative Example 1

As a comparative example, an FTO film was directly formed on a base of SUS 304 plate for a separator without forming a thermal oxide film explained at 1-1 and 1-2 mentioned above. The FTO film was directly formed on the base similarly formed according to 1-3 mentioned above.

### Evaluation Test

In the evaluation test, tests to generate power were conducted on the FTO film of the layered structure of the Practical Example 1, the FTO film of the layered structure of the Practical Example 2, and the FTO film of the layered structure of the Comparative Example 1. In the tests to generate power, the FTO film of each Example was positioned on one side of one of a pair of separators, which were arranged at both sides of a membrane electrode assembly (MEA) with an effective area of 50 cm² to form a single fuel cell. The MEA, in which electrode sheets of carbon fibers were adhered to both sides of a polymer electrolyte body of perfluorinated sulfonic acid, was used. The MEAs used in the tests of the FTO films of the Practical Example 2 and the Comparative Example 1 were commercially available MEAs, which were better in a self-made MEA used in the test of the FTO film of the Practical Example 1.

Using single fuel cells formed as mentioned above, pure hydrogen as fuel gas was supplied to the side of fuel cell with utilization ratio of hydrogen to be 50%, and air was supplied to the side of an oxidant electrode with utilization ratio of oxygen to be 25%. The fuel gas from a hydrogen cylinder was bubbled in ion exchange water set at a temperature of 80° C. and supplied with water vapor. Also, air supplied from an oil and grain-free air compressor (produced by ANEST IWATA Corporation) was bubbled in ion exchange water set at a temperature of 80° C. and supplied with water vapor.

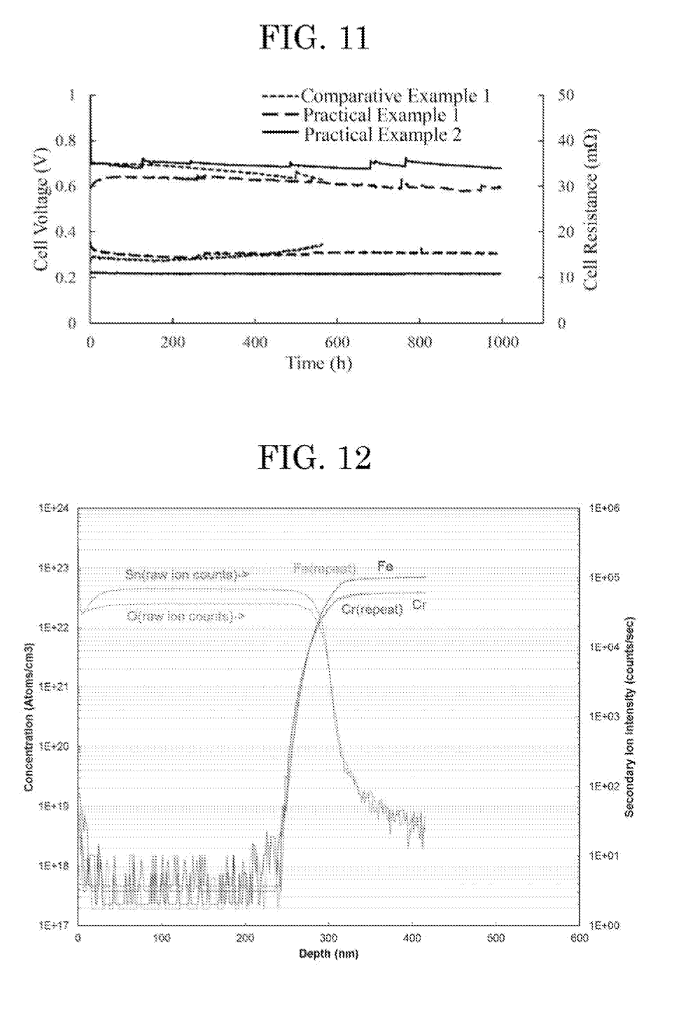

FIG. 11 shows cell voltage and cell resistance values under a constant load of current density that is 0.25 A/cm² with lapse of time.

Regarding the FTO film obtained in the Comparative Example 1, the cell resistance of the FTO film started to rise and the cell voltage of the FTO film started to fall after approximately 250 hours passed. After 500 hours passed, the test to generate power using the FTO film of the Comparative Example 1 was stopped, and the single cell was disassembled and found that there was a separation of the FTO film from the separator arranged at the hydrogen fuel electrode (anode) side.

Regarding the FTO film obtained in the Practical Example 1, the cell resistance of the FTO film did not show a tendency to rise, and even after 1000 hours passed, a separation of the FTO film was not found.

Furthermore, regarding the FTO film obtained in the Practical Example 2, the cell resistance of the FTO film did not show a tendency to rise, and even after 1000 hours passed, a separation of the FTO film was not found. Also, as clearly shown in FIG. 11, the layered structure obtained in the Practical Example 2 is superior to the layered structure of the Comparative Example 1 in thermistor characteristics.

### Reference Example 1

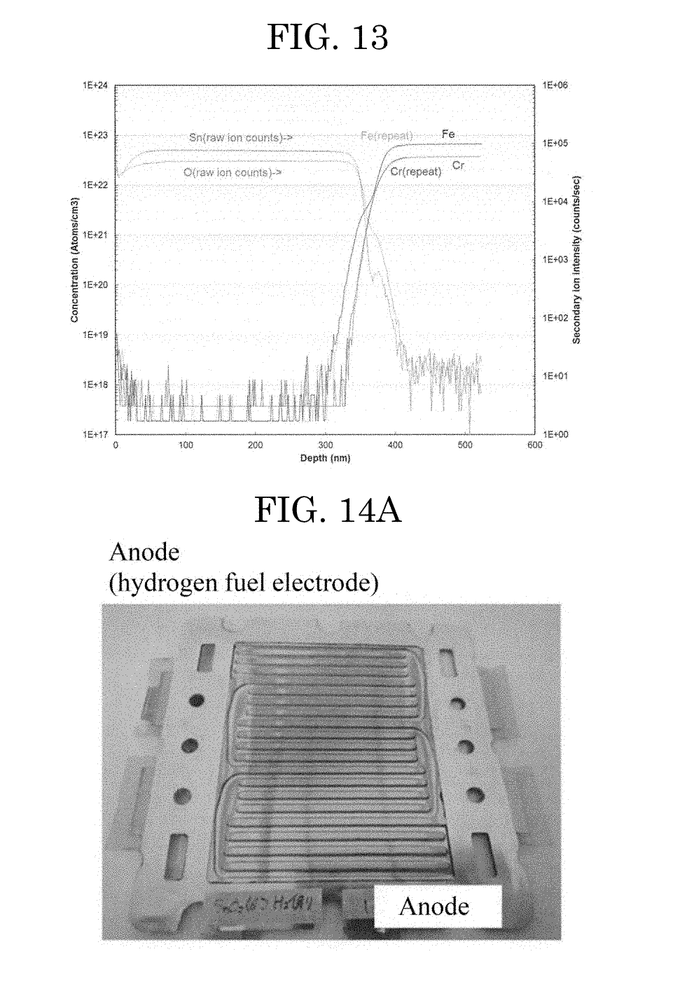

A layered structure obtained under the same conditions as the conditions in the Practical Example 1 and a layered structure in which an FTO film is directly formed on a base of SUS 304 plate for a separator without forming a thermal oxide film at 1-1 and 1-2 under the same conditions as the conditions in the Comparative Example 1 mentioned above were analyzed by secondary-ion mass spectrometry (SIMS). FIG. 12 shows the result of SIMS analysis of the layered structure obtained under the same conditions as the conditions in the Practical Example 1. FIG. 13 shows the result of SIMS analysis of the layered structure in which the FTO film is directly formed on the base of SUS 304 plate. As clearly shown in FIG. 12 and FIG. 13, the thermal oxide film of the layered structure according to an embodiment of a present inventive subject matter contains 10 at. % or less of iron oxide than the base of the layered structure obtained according to the conditions of the Comparative Example 1.

A layered structure according to a present inventive subject matter may be an electrically-conductive member. A layered structure according to an embodiment of a present inventive subject matter is expected to have long-term stability of an electrical characteristic and corrosion resistance, and thus, is able to be used for various electronic parts. Furthermore, a layered structure of a present inventive subject matter is able to be used in a severe environment requiring a corrosion resistance and used for exterior of electronic devices, lighting systems, buildings and vehicles, for example. If a layered structure of a present inventive subject matter is used in a fuel cell, long-term stability in electrical properties and corrosive resistance are expected.

Furthermore, while certain embodiments of the present inventive subject matter have been illustrated with reference to specific combinations of elements, various other combinations may also be provided without departing from the teachings of the present inventive subject matter. Thus, the present inventive subject matter should not be construed as being limited to the particular exemplary embodiments described herein and illustrated in the Figures, but may also encompass combinations of elements of the various illustrated embodiments.

Many alterations and modifications may be made by those having ordinary skill in the art, given the benefit of the present disclosure, without departing from the spirit and scope of the inventive subject matter. Therefore, it must be understood that the illustrated embodiments have been set forth only for the purposes of example, and that it should not be taken as limiting the inventive subject matter as defined by the following claims. The following claims are, therefore, to be read to include not only the combination of elements which are literally set forth but all equivalent elements for performing substantially the same function in substantially the same way to obtain substantially the same result. The claims are thus to be understood to include what is specifically illustrated and described above, what is conceptually equivalent, and also what incorporates the essential idea of the inventive subject matter.

### REFERENCE NUMBER DESCRIPTION

1 a film (layer)-formation apparatus

2a a carrier gas supply device

2b a diluted carrier gas supply device

3a a flow-control valve of carrier gas

3b a flow-control valve of diluted carrier gas

4 a mist generator

4a a raw material solution

4b an atomized droplet

5 a vessel

5a water

6 an ultrasonic transducer

7 a film (layer)-formation chamber

8 a hot plate

9 a supply tube

10 a base

11 an exhaust port

12 a separator (which may be called as a bipolar plate).

13 an uneven shape (a recessed portion)

14 an uneven shape (a projected portion)

15 a manifold

23 an uneven surface

31 a power generation system

32 a fuel cell system

33 a fuel cell processor

34 a fuel cell stack

35 an inverter

36 a controller

37 a fan blower

38 a heat exchanger

39 a distribution switch board

40 a load

41 tap water

42 hot water

43 a water storage tank

50 a base

51 a thermal oxide film

52 a film containing an electrically-conductive oxide

100 a layered structure

200 a layered structure

300 a layered structure

300′ a layered structure

1000 a fuel cell

1. A layered structure comprising:
a base comprising a first metal as a major component and a second metal that is different from the first metal; and
a thermal oxide film of the base arranged on the base and comprising an oxide of the first metal and an oxide of the second metal,
the first metal comprised in the base being more in atomic composition ratio than the second metal comprised in the base,
the first metal of the oxide comprised in the thermal oxide film being less in atomic composition ratio than the first metal comprised in the base, and
the second metal of the oxide comprised in the thermal oxide film being equal to or more in atomic ratio than the first metal of the oxide comprised in the thermal oxide film.

2. The layered structure of claim 1, wherein
the first metal comprises iron (Fe).

3. The layered structure of claim 1, wherein
the first metal comprises aluminum (Al).

4. The layered structure of claim 1, wherein
the second metal comprises a metal selected from metals of Group 6 in the periodic table.

5. The layered structure of claim 1, wherein
the base comprises stainless steel.

6. The layered structure of claim 1, wherein
the base comprises an uneven shape on at least a part of a surface of the base.

7. The layered structure of claim 1, wherein
the base comprises an uneven surface.

8. The layered structure of claim 6, wherein the uneven shape of the base comprises grooves.

9. The layered structure of claim 1, wherein the base comprises a bipolar plate.

10. The layered structure of claim 1 further comprising:
a film comprising an electrically-conductive oxide and arranged on at least a part of the thermal oxide film.

11. The layered structure of claim 10, wherein
the electrically-conductive oxide comprised in the film comprises at least one metal selected from among tin (Sn), titanium (Ti), zirconium (Zr), zinc (Zn), indium (In) and gallium (Ga).

12. The layered structure of claim 10, wherein
the film further comprises at least one chemical element selected from among niobium (Nb), fluorine (F), antimony (Sb), bismuth (Bi), selenium (Se), tellurium (Te), chlorine (Cl), bromine (Br), iodine (I), vanadium (V), phosphorus (P) and tantalum (Ta).

13. An electronic device comprising:
the layered structure of claim 1.

14. The electronic device of claim 13, wherein the electronic device comprises a fuel cell.

15. A system comprising:
the electronic device of claim 13; and
a central processing unit electrically connected to the electronic device.

16. A layered structure comprising:
a base comprising a first metal as a major component and a second metal that is different from the first metal;
a thermal oxide film of the base arranged on the base and comprising an oxide of the first metal and an oxide of the second metal; and
a film comprising an electrically-conductive oxide and arranged on at least a part of the thermal oxide film,
the first metal comprised in the base being more in atomic composition ratio than the second metal comprised in the base,
the first metal of the oxide comprised in the thermal oxide film being less in atomic composition ratio than the first metal comprised in the base, and
the second metal of the oxide comprised in the thermal oxide film being equal to or more in atomic ratio than the first metal of the oxide comprised in the thermal oxide film.

17. The layered structure of claim 16, wherein
the electrically-conductive oxide comprised in the film comprises at least one metal selected from among tin (Sn), titanium (Ti), zirconium (Zr), zinc (Zn), indium (In) and gallium (Ga).

18. The layered structure of claim 16, wherein
the first metal comprises iron (Fe) and/or aluminum (Al).

19. The layered structure of claim 16, wherein
the second metal comprises a metal selected from metals of Group 6 in the periodic table.

20. The layered structure of claim 16, wherein
the second metal comprises chromium (Cr).

21. The layered structure of claim 16, wherein
the thermal oxide film is in a range of 1 nm to 100 nm in thickness.

22. The layered structure of claim 16, wherein
the base comprises stainless steel.
